(19) United States
(12) Patent Application Publication
(10) Pub. No.: US 2025/0248291 A1
(43) Pub. Date: Jul. 31, 2025

(54) DISPLAY ELEMENT HAVING SELF-LUMINOUS DISPLAY PANEL

(71) Applicant: Continental Automotive Technologies GmbH, Hannover (DE)

(72) Inventors: Kai Hohmann, Babenhausen (DE); Andreas Brüninghaus, Wiehl (DE); Jürgen Bäthis, Wetzlar (DE)

(73) Assignee: Continental Automotive Technologies GmbH, Hannover (DE)

(21) Appl. No.: 19/009,086

(22) Filed: Jan. 3, 2025

(30) Foreign Application Priority Data
Jan. 4, 2024 (DE) 10 2024 200 090.6

(51) Int. Cl. H10K 59/80; H10K 102/00

(52) U.S. Cl. CPC H10K 59/8792; H10K 2102/311

(57) ABSTRACT

The present disclosure relates to a display element comprising a substrate, a self-luminous display panel, which is arranged on the substrate and has metallically reflective elements on its lower side facing toward the substrate, a surface screen, to which the upper side of the display panel facing away from the substrate is connected, and a reflected light suppression layer, wherein the reflected light suppression layer has a polarization-independent transmission between 10% and 30%.

### CROSS REFERENCE TO RELATED APPLICATIONS

This U.S. patent application claims the benefit of German patent application No. 10 2024 200 090.6, filed Jan. 4, 2024, which is hereby incorporated by reference.

### TECHNICAL FIELD

The present disclosure relates to a display element having self-luminous display panel. Self-luminous display panels, such as OLEDs (OLED: organic light-emitting diode), generally have a lower luminance than non-self-luminous display elements, but are capable of also actually displaying black display content in black.

### BACKGROUND

Non-self-luminous transmissive display elements, such as LCDs (LCD: liquid crystal display), require a backlight for image representation. The task of the backlight is here to illuminate the display element as uniformly as possible over the entire active surface in order to produce a display that is as homogeneous as possible right up to the peripheral region. A display that is as bright as possible is achieved due to the fact that the alignment of a liquid crystal layer of the display element in combination with the alignment of polarizing filters permits maximum transmission. A dark or black display content, e.g. in the peripheral region, is achieved by way of minimal transmission, which, in contrast to self-luminous displays, is here always greater than zero. A high luminance is achieved in non-self-luminous display elements by a correspondingly bright backlight.

Self-luminous display panels often have a plurality of metallically reflective elements in comparison to non-self-luminous displays (for example, LCD). In OLEDs, for example, the active OLED surface is constructed from metallic tracks and actuation electrodes under the light-emitting pixels due to the current-based actuation. OLEDs are therefore generally metallically reflective and have reflections of greater than 50%. To suppress these reflections and increase the contrast, OLEDs have a circular polarization filter on the surface, which absorbs incident light reflected by the OLED surface, due to which the surface appears black. This is at the cost of a reduced luminance, since circular polarization filters are only to an extent of approximately 40% light-transmissive, thus have a low transmission.

Arranging a light-absorbing layer behind an actively emitting OLED layer is known from US 2004/135499 A1. Externally incident light which passes this OLED layer is therefore absorbed before it is reflected by metallically reflective elements arranged behind it. However, a reflection on metallically reflecting elements located in front of this OLED layer thus cannot be suppressed. According to an alternative solution indicated therein, a black layer, also referred to as a black matrix, is provided which is only light-transmissive in the area of the self-luminous pixels, but is light-opaque in all intermediate areas between the self-luminous pixels. A majority of the light generated by the self-luminous pixels is absorbed by the black layer and therefore does not contribute to the luminance. The black layer heats up in this case, which results in heating of the heat-sensitive OLED layer, and thus negatively influences its service life and its luminous properties. A display element improved in comparison therewith is desired.

### SUMMARY

A display element according to the disclosure has a substrate, a self-luminous display panel, which is arranged on the substrate and has metallically reflective elements on its lower side facing toward the substrate, a surface screen, to which the upper side of the display panel facing away from the substrate is connected, and a reflected light suppression layer. The reflected light suppression layer has a polarization-independent transmission between 10% and 30% here.

This has the following advantage, among others: Light that is externally incident on the display element, enters the display element and is reflected by the metallically reflective elements is attenuated by 91% to 99% by the reflected light suppression layer, while the light emitted by the display panel is only attenuated by 30% to 10%. The light emitted by the display panel is therefore hardly influenced by reflections due to externally incident light. The self-luminous display panel furthermore does not require a backlight and may therefore be designed in a thinner and more space-saving manner. A thin display panel has the advantage of being bendable, due to which it may be adapted well to a curved shape of the surface screen. Such a curved shape is often desired. If the self-luminous display panel is based on OLED technology (OLED: organic light-emitting diode), in which a circular polarizer is typically used as a reflected light suppression layer, the reflected light suppression layer may instead be designed as a decorative element without this additionally reducing the brightness of the emitted light. Instead, the decorative element is accordingly designed so that it provides the required reflection avoidance. A plastic such as polyimide, for example, is provided as the substrate for the rear side of the self-luminous display panel. Polycarbonate, for example, is provided as the material for the surface screen, which substantially specifies the planar or curved shape of the display element. This enables a curved shaping. The self-luminous display panel is based, for example, on OLEDs or on another self-luminous technology, which has a lower luminance than externally illuminated technologies, in which a very high luminance is achievable by a suitable backlight. The metallically reflective elements are, for example, actuation electrodes of an OLED panel. According to an embodiment according to the disclosure, the reflected light suppression layer may also be embodied as deformed glass, which is printed with a decoration.

According to an embodiment according to the disclosure, the reflected light suppression layer has a rough, matte surface. Externally incident light is therefore already scattered upon entering the display element, by which dazzling peak reflections are avoided.

According to an embodiment according to the disclosure, the self-luminous display panel has at least one emitting area and one non-emitting area, wherein the non-emitting area is provided with a compensation element. The compensation element compensates for a difference of the reflectivity, which difference typically exists between the emitting area and the non-emitting area. The compensation element is applied, for example, directly to the non-emitting area. The compensation element is attached, for example, to another component, but is arranged in the area of the non-emitting area. The other component is, for example, the surface screen. The compensation element is, for example, printed on, adhesively bonded, or applied in another way or, for example, arranged as a separate element. The compensation element may also be, for example, a circular polarization filter, which completely covers the non-emitting area.

According to one embodiment according to the disclosure, the compensation element is designed to bring a color distance ΔE of the emitting area to the non-emitting area less than a predetermined value ΔEₘₐₓ, preferably to a predetermined value less than two. This has the following advantage, among others: Such a low color distance is only established by the observer upon particularly attentive observation. In particular if the display element according to the disclosure is used in a means of transportation, which offers nearly continuously a distraction of an observer, for example, due to driving noises, driving movements, changing ambient impressions, or changing display contents, almost no observer will apply the attentiveness required to recognize such a small color distance. An increased expenditure to bring the color distance below the predetermined value is thus superfluous.

According to an embodiment according to the disclosure, the color distance ΔE between emitting area and non-emitting area is mapped by an RAL standard. The self-luminous display panel is preferably measured before the production of the display element so, or designed so, that the color distance ΔE is in a format suitable for printing inks, preferably according to an RAL standard. This has the following advantage, among others: The compensation element may be an imprinted ink layer, wherein the suitable ink is ascertainable without problems and reliably according to the RAL standard.

According to an embodiment according to the disclosure, a partially transparent layer is arranged between the surface screen and the self-luminous display panel. This has the following advantage, among others: By means of the partially transparent layer, the required transparency between surface of the display element and self-luminous display panel is matched, even if different batches of self-luminous display panels or different batches of surface screens deviate from one another in their optical properties. This increases the flexibility in the production upon the selection of the components used. The partially transparent layer is, for example, an incorporated film, an applied coating, a partially transparent optically clear adhesive (OCA), or the like.

According to an embodiment according to the disclosure, the partially transparent layer has the compensation element. Fewer components are therefore required or the assembly is simplified.

According to an embodiment according to the disclosure, the display element is deformable or movable by means of a deformation element in operation. A kinematic effect or a haptic effect is therefore achievable. A specific surface element of the display element may be able to be both optically and haptically highlighted here. It is therefore perceptible to the user, by which the operating safety is increased, because it enables the user to concentrate their eyes on the driving process or other important optical impressions. This is enabled according to the disclosure without optical impairment, which would occur if a circular polarization filter were used, which likewise deforms upon deformation and would change in its optical properties in this case.

A display element according to the disclosure is preferably used to implement a display with disappearance technology, for example in a means of transport or in a household appliance. The decoration may be used to simulate, for example, a wood look, a carbon look or an appearance of a metallic surface. In the automotive sector, but also in household appliances and in other areas of application, there is an observable trend that operating or display functions should be as invisible as possible in the switched-off state in order to achieve a reduced design with smooth, generous surfaces. Technical elements should be visible only when they are needed. Such disappearance technologies are known, for example, under the names “Shytech” or “Camouflage”. To realize disappearance technology, for example, a display element may be arranged behind a design surface. Suitable transmissive, decorative surfaces for this application may be made in real material, e.g. wood, stone, leather, imitation leather, etc., and may also be manufactured in plastic or glass technology. The decoration is applied by means of printing technology onto the surface of a cover panel or alternatively onto a separate film surface. The decoration may be applied, for example, as a transmissive print or in the form of a perforated mask.

### BRIEF DESCRIPTION OF THE DRAWINGS

Further features of the present disclosure will become apparent from the following description and the appended claims in conjunction with the figures, wherein:

FIG. 1 schematically shows a sectional view of a display element;

FIG. 2 schematically shows a top view corresponding to FIG. 1;

FIG. 3 schematically shows a sectional view of a display element;

FIG. 4 shows a three-dimensional view of a self-luminous display panel;

FIG. 5 shows a side view of a display element according to the disclosure;

FIG. 6 schematically shows a display behind a decorative surface;

FIG. 7 shows a display element according to the disclosure; and

FIG. 8 shows reflection examples.

### DETAILED DESCRIPTION

For a better understanding of the principles of the present disclosure, embodiments of the disclosure are explained in more detail below with reference to the figures. Identical reference signs are used for identical or functionally identical elements in the figures and are not necessarily described again for each figure. It goes without saying that the disclosure is not restricted to the embodiments represented and that the features described can also be combined or modified without departing from the scope of protection of the disclosure as defined in the appended claims.

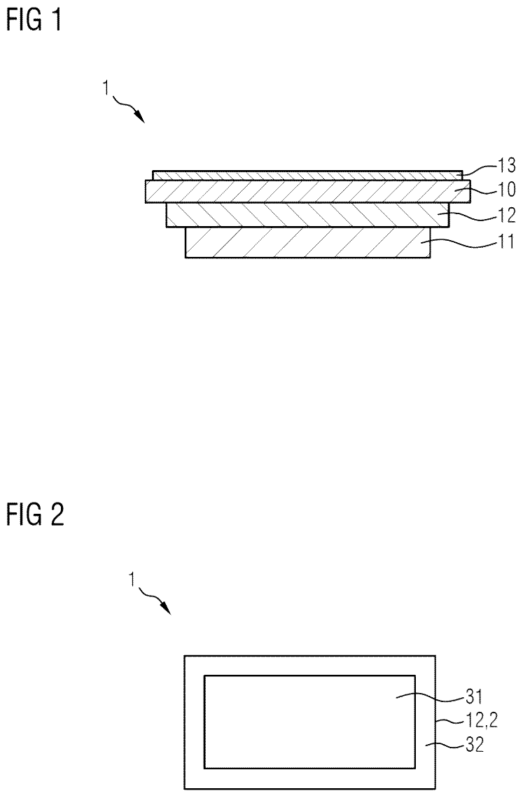

FIG. 1 schematically shows a sectional view of a display element 1 having a non-self-luminous LCD panel 12, on the lower side of which a backlight 11 is arranged and on the upper side of which a surface screen 10 is arranged. A decorative element 13 is arranged on the side of the surface screen 10 facing away from the LCD panel 12. The surface screen 10 is transparent, while the decorative element 13 has a decorative print, for example, and is therefore only partially transmissive. The LCD panel 12 has pixels (not shown here) which are arranged in rows and columns and are switchable to light-transmissive and light-opaque. Depending on the switching state of a pixel, it blocks light coming from the backlight 11 or lets it pass. The backlight 11 has a sufficiently high luminance that the light also passes the partially transparent decorative element 13.

FIG. 2 shows a top view of the LCD panel 12 of FIG. 1. An emitting area 31, the dimension of which corresponds to the external dimensions of the backlight 11, are seen. A non-emitting area 32, which corresponds to the external dimensions of the LCD panel 12, is located around the emitting area 31. If a self-luminous display panel 2, for example, an OLED panel, is provided instead of an LCD panel 12, the emitting area 31 corresponds to a so-called “active area” and the non-emitting area 32 corresponds to a wiring area, a so-called “non-visible area”.

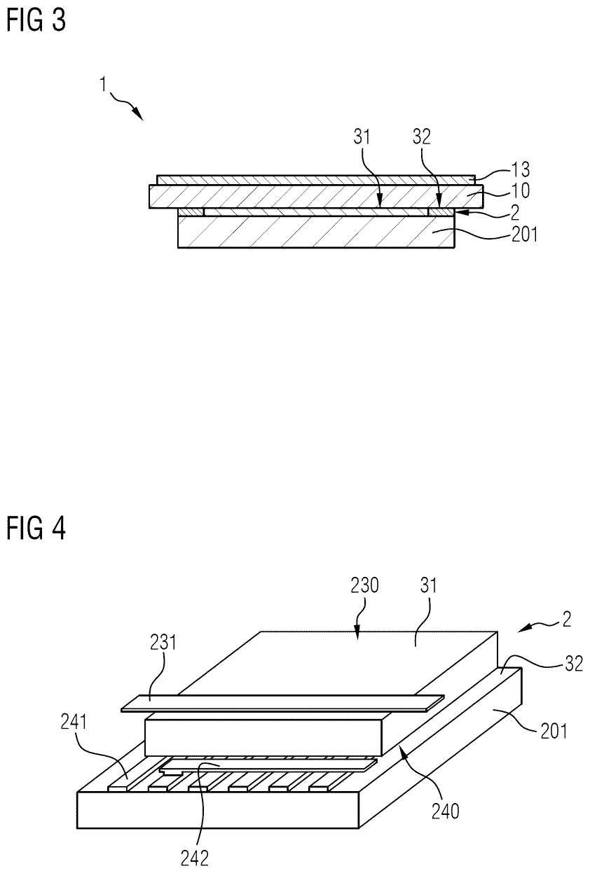

FIG. 3 schematically shows a side view of a display element 1 having a self-luminous display panel 2, which is arranged on a substrate 201. A surface screen 10 and a decorative element 13 are located on the side of the display panel 2 facing away from the substrate 201. It is seen that the display panel 2 is significantly thinner than the substrate 201. The self-luminous display panel 2 has an emitting area 31 and a non-emitting area 32.

FIG. 4 shows a schematic three-dimensional view of the self-luminous display panel 2 and the substrate 201. Metallic conductor tracks 241, several of which are shown as examples, are arranged on the lower side 240 of the display panel 2 or on the surface of the substrate 201 facing toward the display panel 2. The conductor tracks 241 arranged on the lower side 240 protrude into the region of the non-emitting area 32. Further conductor tracks 242, one of which is shown as an example, are located in the region of the non-emitting area 32. These are used to connect the conductor tracks 241 to one another or to further actuation elements. Metallic conductor tracks 231, one of which is shown as an example, are also applied to the upper side 230 of the display panel 2. These conductor tracks 231 are part of a touch-sensitive or proximity-sensitive input surface (otherwise not shown here), which is also referred to as a touchscreen. The conductor tracks 231 arranged on the upper side 230 also protrude beyond the emitting area 31 into the region of the non-emitting area 32. The metallic conductor tracks 231, 241, 242 are thin, so that they are transparent to light. However, they also reflect a certain proportion of the light incident thereon. Since multiple layers of conductor tracks 241, 242, 231 are arranged one on top of another in the region of the non-emitting area 32, the non-emitting area 32 reflects more strongly than the emitting area 31.

FIG. 5 shows a side view of a display element 1 according to the disclosure. In contrast to the display elements described further above, it does not have a planar form but rather is curved multiple times. The substrate 201, on which the self-luminous display panel 2 is arranged, is seen. The emitting area 31 is located in its central region, the non-emitting area 32 is located in its edge region. The display panel 2 is connected to a surface screen 10 by means of a transparent adhesive layer 204. Compensation elements 206, which are located in the region of the non-emitting area 32, are provided in the edge region of the surface screen 10. They are shown here as an ink layer printed on the lower side of the surface screen 10, in the region of which the resulting adhesive layer 204 is thinner than in the region of the non-emitting area 32. A decorative element 13 is arranged on the side of the surface screen 10 facing away from the display panel 2 as a reflected light suppression layer 3. The reflected light suppression layer 3 has a polarization-independent transmission T, which is in the range of 10%<T<30%. The upper side 330 of the reflected light suppression layer 3 and/or the lower side 340 of the reflected light suppression layer 3 is a rough, matte surface. It therefore scatters light incident thereon. The compensation element 206 is designed to match the color impression which an observer of the display panel 2 receives so that the color distance ΔE between the emitting area 31 and the non-emitting area 32 is less than a predetermined value, here ΔE<2. According to one variant, it is provided that a partially transparent adhesive layer 205 is provided instead of a transparent adhesive layer 204. According to one variant, the compensation element 206 is not printed on the surface screen 10, but rather is part of a partially transparent layer 205′. This layer 205′ is, for example, a double-sidedly adhesive film, in the edge region of which the compensation element 206 is arranged.

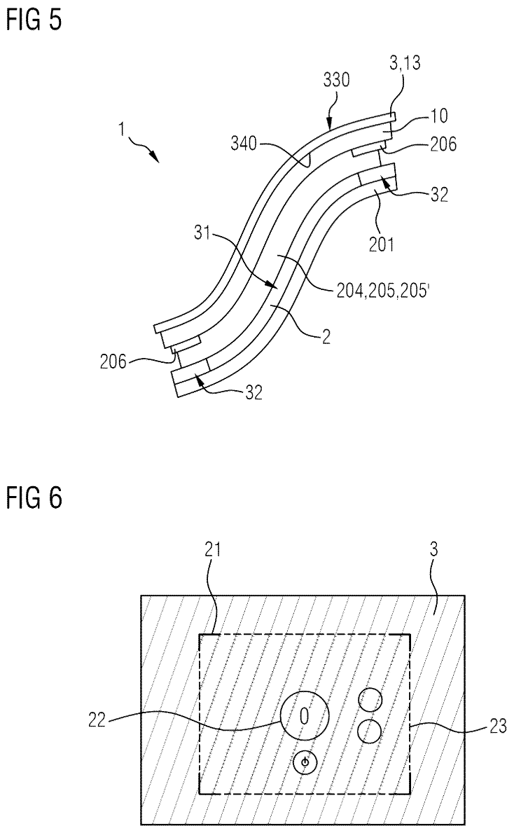

FIG. 6 schematically shows a display behind a decorative surface. It shows the effect of a known display panel arranged behind a light-transmissive layer on a viewer. In the example shown, the light-transmissive layer is a decorative element 3. The decoration of the decorative element 3 is indicated by shading in the figure. The dimensions of the display panel are indicated by means of corner elements 21. Multiple symbols 22 are displayed by the display panel. If the decorative element 3 is to consist of an authentic material, such as real wood, real metal, or also real stone, it is to be taken into consideration that such materials are largely opaque or have a very low transmission. This is indicated in the figure by the dashed lines within the display region 23 that are drawn in addition to the shading.

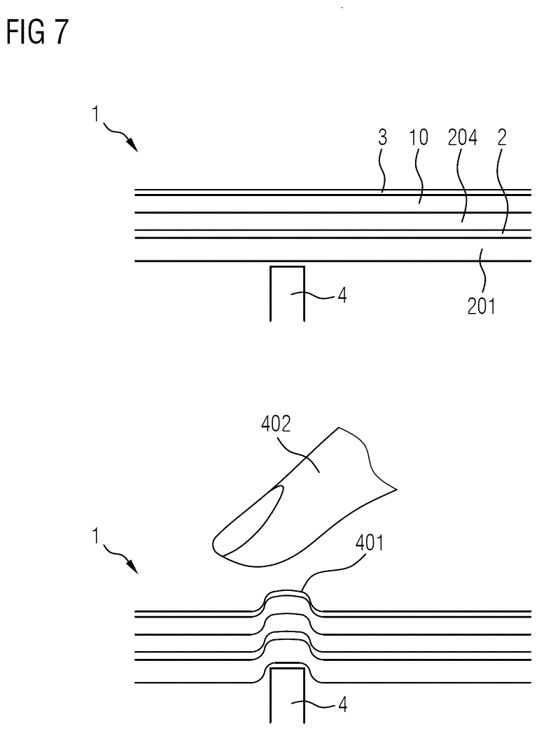

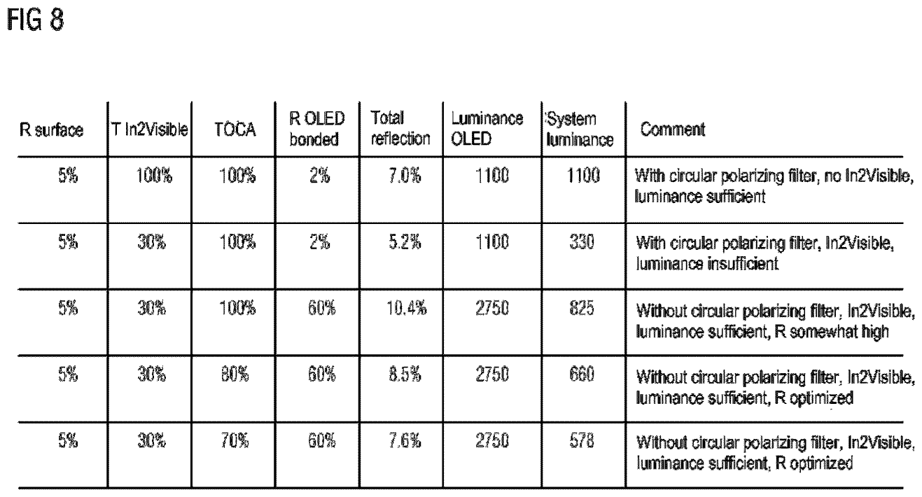

FIG. 7 shows a display element 1 according to the disclosure having a deformation element 4 in two different states. The substrate 201, the self-luminous display panel 2, the transparent adhesive layer 204, the surface screen 10, and the reflected light suppression layer 3 is seen in the upper region of the figure. In the embodiment described here, the materials of all of these elements are designed as flexibly deformable, at least in the region of the deformation element 4. The deformation element 4 is located below the substrate 201 in its non-deflected position. The deformation element 4 is located in its deflected position in the lower region of the figure. In this case, it deforms the layers of the display element 1 located above it, so that a deformed region 401 forms on its surface. A user may feel this, for example, by means of their finger 402. The display element 1 according to the disclosure therefore conveys a haptic effect. In this way, a shape-changing operating element is implemented, which is often also referred to by the expression morphing controls. If the deformation element 4 is designed as more comprehensive, instead of the rather locally deformed region 401 described here, comprehensive bending or the change of a radius of curvature of the display element 1 may be achieved. A flexibility of the materials used which is not as high is often already sufficient for this purpose.

Display elements in the vehicle are receiving more and more individualization, such as so-called direct view displays, which can only be observed directly from a specific direction, but do not display anything from directions deviating therefrom, so-called pillar-to-pillar displays, which extend nearly from the left to the right A-pillar, so-called In2Visible, disappearance technology, or Shytech displays, the display elements of which are concealed behind a decorative element, and of which only the currently lighted display regions are visible through the decorative element, or so-called scenic view displays, which extend in the lower region of the windshield with low height but very great width. In particular combinations of these types of displays, such as already disclosed Pillar2Pillar displays having a user interface which is designed as an In2Visible display, have proven to be ergonomically reasonable. Display elements or displays are often also referred to as display screens herein. In2Visible displays initially appear like a passive surface, which then converts into a display surface when the display located behind it is switched on. The passive surface may assume any decorative representation (e.g., burl wood, carbon, plain, . . . ), since this surface may be made by a print on a plastic film or a glass surface. In addition, In2Visible surfaces are distinguished in that the surfaces only have limited transmission, which has to be compensated for in the case of LCDs by an elevated luminance of the backlight, preferably FALD (full array local dimming: the entire backlit surface may be adapted locally in its brightness). However, LCDs have the disadvantage that they cannot be specially curved or deformed in order to follow the design wishes of the interior cockpit. A physically reasonable limit of the bending is radii of curvature in the range of approximately 700 mm to 800 mm. Display technologies which permit improved curvature, such as OLED, have the disadvantage that they do not have sufficient luminance in order to compensate for the transmission losses of an In2Visible surface. Since OLEDs are self-luminous and since the active OLED surface, due to the current-related actuation, consists of metallic tracks and electrodes under the emitting pixels, OLEDs are generally metallically reflective and have reflections of R>50%. To suppress these reflections and increase the contrast, OLEDs have a circular polarization filter on the surface, which absorbs incident light reflected from the OLED surface and therefore causes the surface to appear black. This advantage is at the cost of reduced luminance, since the circular polarization filters are only to an extent of approximately 40% light-transmissive or have a low transmission. Dispensing with such a circular polarization filter on the OLED results in a further problem. While the OLED having circular polarization filter has a homogeneous appearance, since the circular polarization filter suppresses all internal reflections, there is now a different appearance between the emitting surface, which consists of a few conductor tracks (preferably metallic, but also made of TCO (transparent conductive oxide)) and electrodes and the so-called non-emitting area (“non-visible area”). This results in a different reflection behavior, which is perceived through the In2Visible surface as an inhomogeneity.

According to the disclosure, a display element, in particular for use in motor vehicles, is proposed for In2Visible applications which achieves a target luminance of typically 800 cd/m² and at the same time a homogeneous appearance is achieved. In particular upon the elimination of the circular polarization filter, inhomogeneities of the different reflection behavior of the emitting and non-emitting regions 31, 32 is compensated for by optical matching of both sides. The plastic OLED display technology is capable of achieving In2Visible surfaces having a radius of curvature less than 800 mm. Polyimide is preferably used as the substrate of the OLEDs, which is bendable as such and enables radii of curvature <10 mm. Therefore, OLEDs are very well suitable mechanically to meet the design requirements for In2Visible surfaces. However, OLEDs for applications in the automotive sector only have illuminants of at most 1000 cd/m² via the circular polarization filter. One essential feature of the invention is to enable the required target brightness of the In2Visible surface for the at least currently existing restricted OLED luminance. For this purpose, the circular polarization filter of the OLEDs is removed to thus increase the luminance by at least a factor of two. Furthermore, the reflections of the OLED surface and the accompanying increased reflection due to the lower transmission of the In2Visible decorative print are compensated for. The incident light is also not reflected as strongly in the direction of the observer due to a matte design of the In2Visible surface. Automotive applications having approximately 800 cd/m² can thus be achieved:
Luminance (L) of OLED with circular polarization filter: 1100 cd/m²
L with OLED and In2Visible surface (T=30%): 330 cd/m² (too low)
But:
L OLED without circular polarization filter (ZP): 2750 cd/m²
L with OLED without circular polarization filter and with In2Visible surface (T=30%): 825 cd/m² (OK)

Reflection examples without circular polarization filter and with/or without partially transparent layer can be inferred from FIG. 8.

To optimize the color difference between emitting and non-emitting OLED layer, a further print, the compensation element 206, is incorporated above the non-emitting area 32 between In2Visible element and OLED. The print may be located on the rear side of the In2Visible element or may be applied on a separate film. For further optimization of the reflection behavior, a partially transparent layer, the adhesive layer 205 or the layer 205′, may be introduced between In2Visible element and OLED. This is produced, for example, in the OCA/bonding material or in an additional film.

According to the disclosure, it is proposed that OLEDs be used in the automotive sector without circular polarization filter to increase the system luminance. An improvement of the reflection behavior of the system is achieved by an adapted transmission of the In2Visible surface, the reflected light suppression layer 3, in the range of 10% to approximately 30%. An improvement of the reflection behavior of the In2Visible system is also achieved by a rough matte surface. A matching of the appearance of the emitting OLED surface with the non-emitting surface (wiring region) of the OLED is achieved by a rear-side compensation print on the In2Visible decorative element (plastic or glass). The print above the non-emitting region is designed here so that it corresponds with the reflection behavior of the emitting region. A matching of the appearance of the emitting surface of the OLED with the non-emitting surface is achieved by an additional film in the stack up, which is printed with the compensation print. The color distance ΔE of the emitting area to the non-emitting area is minimized. A ΔE value of ΔE<2 is typically desired. Preferably, the ΔE value is mapped by a RAL standard and therefore a printable ink. Preferably, a partially transparent film, a partially transparent coating, or a partially transparent OCA with, for example, 70%-90% transmission is incorporated to optimize the reflection behavior of the overall system in combination and matching with the In2Visible surface. Some luminance is absorbed here, but the reflections and therefore the overall impression are further improved. The partially transparent film is combined with rear-side compensation print as a common part, which is incorporated between In2Visible surface and OLED. The following exemplary embodiments are enabled according to the invention: An In2Visible display having various radii of curvature. Multi-displays having variable radii and bent design language. Pillar2Pillar displays having variable radii and bent design language. In2Visible surfaces having two or more different displays and two or more different radii of curvature. In2Visible displays having kinematic effects, in which the surface or the shape and geometry can be made variable and is accordingly individually adjustable by motors. Further applications in rear seat displays, roof displays, door displays, or other display units are enabled according to the disclosure.

1. A display element comprising:
a substrate,
a self-luminous display panel, which is arranged on the substrate and has metallically reflective elements on its lower side facing toward the substrate,
a surface screen, to which the upper side of the display panel facing away from the substrate is connected, and
a reflected light suppression layer,
wherein the reflected light suppression layer has a polarization-independent transmission between 10% and 30%.

2. The display element as claimed in claim 1, wherein the reflected light suppression layer has a rough, matte surface.

3. The display element as claimed in claim 1, wherein the self-luminous display panel has at least one emitting region and one non-emitting region, and wherein the non-emitting region is provided with a compensation element.

4. The display element as claimed in claim 3, wherein the compensation element is designed to bring a color distance of the emitting region to the non-emitting region less than a predetermined value, preferably to a predetermined value less than two.

5. The display element as claimed in claim 4, wherein the color distance between emitting region and non-emitting region is mapped by an RAL standard.

6. The display element as claimed in claim 1, wherein a partially transparent layer is arranged between the surface screen and the self-luminous display panel.

7. The display element as claimed in claim 3, wherein a partially transparent layer has the compensation element.

8. The display element as claimed in claim 6, wherein the partially transparent layer has a compensation element.

9. The display element as claimed in claim 1, wherein the display element is deformable in operation by a deformation element.

10. A display having disappearance technology comprising a display element, the display element comprising:
a substrate,
a self-luminous display panel, which is arranged on the substrate and has metallically reflective elements on its lower side facing toward the substrate,
a surface screen, to which the upper side of the display panel facing away from the substrate is connected, and
a reflected light suppression layer,
wherein the reflected light suppression layer has a polarization-independent transmission between 10% and 30%.
